(19) United States
(12) Patent Application Publication
(10) Pub. No.: US 2016/0293118 A1
(43) Pub. Date: Oct. 6, 2016

(54) DISPLAY DEVICE

(71) Applicant: SAMSUNG DISPLAY CO, LTD., Yongin-si (KR)

(72) Inventors: JUNHYUN PARK, SUWON-SI (KR); SUNGHWAN KIM, YONGIN-SI (KR); SEYOUNG SONG, HWASEONG-SI (KR); KYOUNGJU SHIN, HWASEONG-SI (KR)

(21) Appl. No.: 14/863,823

(22) Filed: Sep. 24, 2015

(30) Foreign Application Priority Data
Mar. 31, 2015 (KR) 10-2015-0045662

(51) Int. Cl. G09G 3/36; G02F 1/1333; G02F 1/1362; H01L 27/12; G02F 1/1368

(52) U.S. Cl. CPC G09G 3/36; H01L 27/124; H01L 27/1255; H01L 27/1248; G02F 1/1368; G02F 1/136213; G02F 1/136286; G02F 1/133345

(57) ABSTRACT

A display device includes a plurality of pixels. Each pixel includes a transistor connected to a corresponding gate line of a plurality of gate lines and a corresponding data line of a plurality of data lines, and a liquid crystal capacitor connected to the transistor. The display device further includes a plurality of switch transistors receiving data voltages and selectively applying the data voltages to odd-numbered data lines and even-numbered data lines of the data lines, and an insulating layer disposed on the transistors and the switch transistors. The insulating layer disposed on a conductive channel of each of the transistors has a first thickness, and the insulating layer disposed on a conductive channel of each of the switch transistors has a second thickness larger than the first thickness.

### CROSS-REFERENCE TO RELATED APPLICATIONS

This application claims priority under 35 U.S.C. §119 to Korean Patent Application No. 10-2015-0045662, filed on Mar. 31, 2015, the disclosure of which is incorporated by reference herein in its entirety.

### TECHNICAL FIELD

Exemplary embodiments of the present inventive concept relate to a display device, and more particularly, to a display device capable of improving the charging rate of pixels in the display device.

### DISCUSSION OF THE RELATED ART

A variety of display devices, such as liquid crystal display devices, organic light emitting display devices, electrowetting display devices, and electrophoretic display devices, are currently being developed.

Display devices generally include a display panel including a plurality of pixels, a gate driving unit providing the pixels with gate signals, and a data driving unit providing the pixels with data voltages.

The pixels receive gate signals through a plurality of gate lines, receive data voltages through a plurality of data lines in response to the gate signals, and charge the data voltages. Each pixel displays a grayscale value corresponding to the charged data voltage. As a result, an image is displayed.

An RC delay phenomenon may be generated on the lines. An RC delay phenomenon refers to a signal delay caused by the self-resistance of the lines and parasitic capacitors. When data voltages are provided to the pixels through the data lines, the data voltages may not be sufficiently charged in the pixels due to the RC delay phenomenon.

### SUMMARY

Exemplary embodiments of the present inventive concept provide a display device capable of improving the charging rate of pixels of the display device.

According to an exemplary embodiment of the inventive concept, a display device includes a plurality of pixels. Each pixel includes a transistor connected to a corresponding gate line of a plurality of gate lines and a corresponding data line of a plurality of data lines, and a liquid crystal capacitor connected to the transistor. The display device further includes a plurality of switch transistors receiving data voltages and selectively applying the data voltages to odd-numbered data lines and even-numbered data lines of the data lines, and an insulating layer disposed on the transistors and the switch transistors. The insulating layer disposed on a conductive channel of each of the transistors has a first thickness, and the insulating layer disposed on a conductive channel of each of the switch transistors has a second thickness larger than the first thickness.

In an exemplary embodiment, an entirety of the insulating layer has the second thickness except for areas in which the conductive channel of each of the transistors is disposed.

In an exemplary embodiment, the insulating layer includes an inorganic material.

In an exemplary embodiment, the insulating layer includes a first sub-insulating layer disposed on the transistors and the switch transistors, and a second sub-insulating layer disposed on the first sub-insulating layer. The first and second sub-insulating layers include different inorganic materials.

In an exemplary embodiment, the first sub-insulating layer includes silicon oxide.

In an exemplary embodiment, the second sub-insulating layer includes silicon nitride.

In an exemplary embodiment, each of the first and second sub-insulating layers disposed on the conductive channel of each of the transistors has a third thickness.

In an exemplary embodiment, the first sub-insulating layer disposed on the conductive channel of each of the switch transistors has a third thickness and the second sub-insulating layer disposed on the conductive channel of each of the switch transistors has a fourth thickness larger than the third thickness.

In an exemplary embodiment, an entirety of the first sub-insulating layer has a third thickness except for areas in which the conductive channel of each of the transistors is disposed, an entirety of the second sub-insulating layer has a fourth thickness except for areas in which the conductive channel of each of the transistors is disposed, and the fourth thickness is larger than the third thickness.

In an exemplary embodiment, the second sub-insulating layer has a thickness larger than about 100 Å and less than or equal to about 1,000 Å.

In an exemplary embodiment, the display device further includes a base substrate. The transistors and the switch transistors are disposed on the base substrate. The display device further includes an organic insulating layer disposed on the insulating layer. Each liquid crystal capacitor includes a pixel electrode connected to a corresponding transistor via a contact hole passing through the insulating layer and the organic insulating layer, a common electrode facing the pixel electrode, and a liquid crystal layer disposed between the pixel electrode and the common electrode.

In an exemplary embodiment, each of the transistors includes a gate electrode connected to the corresponding gate line, a source electrode connected to the corresponding data line, a drain electrode connected to the pixel electrode, and a semiconductor layer disposed between the gate electrode and the source and drain electrodes. The semiconductor layer forms the conductive channel of the transistor between the source electrode and the drain electrode.

In an exemplary embodiment, each of the gate lines receives a gate signal including a first period and a second period. The switch transistors include a plurality of first switch transistors receiving the data voltages during the first period and applying the data voltages to the odd-numbered data lines, and a plurality of second switch transistors receiving the data voltages during the second period and applying the data voltages to the even-numbered data lines.

In an exemplary embodiment, each of the first switch transistors includes a first gate electrode receiving a first switch signal, a first source electrode receiving a corresponding data voltage of the data voltages, a first drain electrode connected to a corresponding odd-numbered data line of the odd-numbered data lines, and a first semiconductor layer disposed between the first gate electrode and the first source and first drain electrodes. The first semiconductor layer forms the conductive channel of a corresponding first switch transistor between the first source electrode and the first drain electrode. Each of the second switch transistors includes a second gate electrode receiving a second switch signal, a second source electrode receiving a corresponding data voltage of the data voltages, a second drain electrode connected to a corresponding even-numbered data line of the even-numbered data lines, and a second semiconductor layer disposed between the second gate electrode and the second source and second drain electrodes. The second semiconductor layer forms the conductive channel of a corresponding second switch transistor between the second source electrode and the second drain electrode.

In an exemplary embodiment, the insulating layer includes silicon nitride.

According to an exemplary embodiment of the inventive concept, a display device includes a gate driving unit providing a plurality of pixels of a display panel with a plurality of gate signals through a plurality of gate lines, a data driving unit providing a demultiplexing unit with a plurality of data signals through a plurality of drive lines, the demultiplexing unit providing the pixels with the data signals through a plurality of data lines, a timing controller generating a gate control signal that controls an operation timing of the gate driving unit, a data control signal that controls an operation timing of the data driving unit, and a switch control signal controlling an operation of the demultiplexing unit, and the display panel. The display panel includes the pixels. Each pixel includes a transistor connected to a corresponding gate line of the gate lines and a corresponding data line of the data lines, a plurality of switch transistors receiving data voltages and applying the data voltages to the data lines, and an insulating layer disposed on the transistors and the switch transistors. The insulating layer disposed on a conductive channel of each of the transistors has a first thickness, and the insulating layer disposed on a conductive channel of each of the switch transistors has a second thickness larger than the first thickness.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a block diagram of a display device according to an exemplary embodiment of the inventive concept.

FIG. 2 illustrates a configuration of a pixel illustrated in FIG. 1 according to an exemplary embodiment of the inventive concept.

FIG. 3 illustrates a configuration of a demultiplexing (demux) unit illustrated in FIG. 1 according to an exemplary embodiment of the inventive concept.

FIG. 4 is a timing diagram illustrating the operation of a demux unit according to an exemplary embodiment of the inventive concept.

FIG. 5 illustrates a cross-sectional view of a display panel in an area in which a transistor of any one pixel illustrated in FIG. 1 and any one switch transistor illustrated in FIG. 3 are disposed according to an exemplary embodiment of the inventive concept.

FIG. 6 shows exemplary experimentation results regarding the source-drain current of switch transistors according to the thickness of a second insulating layer disposed on the switch transistors according to an exemplary embodiment of the inventive concept.

FIG. 7 illustrates a cross-sectional view of a display panel of a display device according to an exemplary embodiment of the inventive concept.

### DETAILED DESCRIPTION OF THE EXEMPLARY EMBODIMENTS

Exemplary embodiments of the present inventive concept will be described more fully hereinafter with reference to the accompanying drawings. In the drawings, the size and relative sizes of layers and regions may be exaggerated for clarity. Like reference numerals may refer to like elements throughout the accompanying drawings.

It will be understood that when an element or layer is referred to as being ‘on’, ‘over’, ‘connected to’, ‘coupled to’, or ‘adjacent to’ another element or layer, it can be directly on, over, connected to, coupled to, or adjacent to the other element or layer, or intervening elements or layers may be present. It will also be understood that when an element or layer is referred to as being “between” two elements or layers, it can be the only element or layer between the two elements or layers, or one or more intervening elements or layers may also be present.

Spatially relative terms such as ‘below’, ‘beneath’, ‘lower’, ‘above’, and ‘upper’ may be used to describe correlations between one element or components and another element or components as illustrated in the drawings. It should be understood that the spatially relative terms include different directions of elements when using or operating the elements in addition to the direction illustrated in the drawings. For example, if the device in the figures is turned over, elements described as “below” or “beneath” or “under” other elements or features would then be oriented “above” the other elements or features. Thus, the exemplary terms “below” and “under” can encompass both an orientation of above and below. In addition, it will also be understood that when a layer is referred to as being “between” two layers, it can be the only layer between the two layers, or one or more intervening layers may also be present.

Although terms such as ‘a first’ and ‘a second’ are used to describe various elements, components and/or sections, these elements, components, and/or sections should not be limited to these terms. These terms are used only to differentiate one element, component, or section from another element, component, or section. Therefore, a first element, a first component, or a first section as described below may be a second element, a second component, or a second section within the inventive concept.

The exemplary embodiments will be described herein with plan views and sectional views as ideal schematic views of the present inventive concept. Accordingly, shapes of exemplary views may be modified according to manufacturing techniques and/or allowable errors. Therefore, the exemplary embodiments of the inventive concept are not limited to the specific shapes illustrated in the exemplary views, but may include other shapes that may be created according to manufacturing processes. Therefore, areas exemplified in the drawings have general properties, and the shapes thereof are used to illustrate a specific shape of an element area and should not be construed as limiting the scope of the present inventive concept.

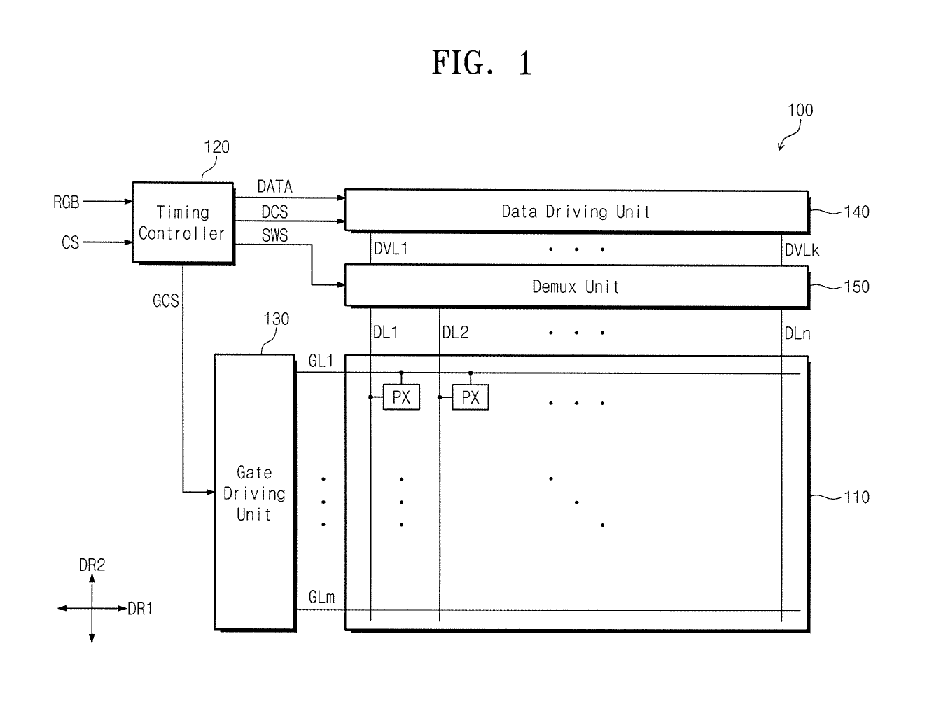

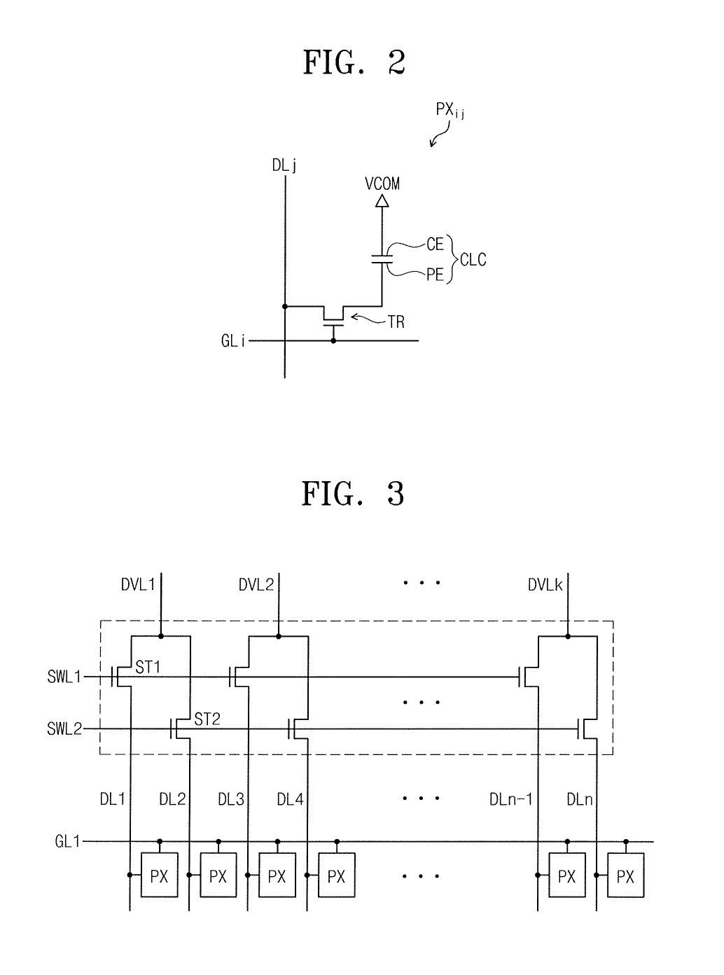

FIG. 1 is a block diagram of a display device according to an exemplary embodiment of the inventive concept. FIG. 2 illustrates a configuration of a pixel illustrated in FIG. 1 according to an exemplary embodiment of the inventive concept.

Referring to FIGS. 1 and 2, the display device 100 according to an exemplary embodiment of the inventive concept includes a display panel 110, a timing controller 120, a gate driving unit 130, a data driving unit 140, and a demultiplexing (demux) unit 150.

The display panel 110 may be one of a variety of display panels such as, for example, a liquid crystal display panel including a liquid crystal layer, an electrophoretic display panel including an electrophoretic layer, an electrowetting display panel including an electrowetting layer, and an organic light emitting display panel including an organic light emitting layer. However, exemplary embodiments of the inventive concept are not limited thereto.

For example, the display panel 110 illustrated in FIG. 1 may be a liquid crystal display panel including first and second substrates facing each other and a liquid crystal layer disposed between the first and second substrates.

The display panel 110 includes a plurality of gate lines GL1 to GLm, a plurality of data lines DL1 to DLn, and a plurality of pixels PX. The gate lines GL1 to GLm extend in a first direction DR1 and are connected to the gate driving unit 130. The data lines DL1 to DLn extend in a second direction DR2 that crosses the first direction DR1 and are connected to the demux unit 150. Herein, m and n are natural numbers greater than or equal to 1.

The data driving unit 140 is connected to a plurality of drive lines DVL1 to DVLk. Herein, k is a natural number equal to n/2. The drive lines DVL1 to DVLk extend in the second direction DR2 and are disposed between the data driving unit 140 and the demux unit 150, and connect the data driving unit 140 and the demux unit 150.

The pixels PX are disposed in areas divided by the gate lines GL1 to GLm and the data lines DL1 to DLn intersecting with each other. Therefore, the pixels PX may be arranged in a matrix form. The pixels PX are connected to the gate lines GL1 to GLm and the data lines DL1 to DLn.

As shown in FIG. 2, each pixel PXij includes a transistor TR and a liquid crystal capacitor CLC connected to the transistor TR. The liquid crystal capacitor CLC includes a pixel electrode PE connected to the transistor TR, a common electrode CE that faces the pixel electrode PE and receives a common voltage VCOM, and a liquid crystal layer disposed between the pixel electrode PE and the common electrode CE.

The transistor TR includes a gate electrode connected to a corresponding gate line GLi of the gate lines GL1 to GLm, a source electrode connected to a corresponding data line DLj of the data lines DL1 to DLn, and a drain electrode connected to the pixel electrode PE of the liquid crystal capacitor CLC. Herein, i and j are natural numbers greater than or equal to 1.

The timing controller 120 receives image signals RGB and a control signal CS from a device external to the display device 100 (e.g., from a system board). The timing controller 120 converts the image signals RGB to a data format that meets specifications allowing the image signals RGB to interface with the data driving unit 140. The timing controller 120 provides image data DATA having the converted data format to the data driving unit 140.

The timing controller 120 generates a gate control signal GCS, a data control signal DCS, and a switch control signal SWS in response to the control signal CS.

The gate control signal GCS is a control signal that controls the operation timing of the gate driving unit 130. The data control signal DCS is a control signal that controls the operation timing of the data driving unit 140. The switch control signal SWS is a control signal that controls the operation of the demux unit 150.

The timing controller 120 provides the gate control signal GCS to the gate driving unit 130, and provides the data control signal DCS to the data driving unit 140. The timing controller 120 provides the switch control signal SWS to the demux unit 150.

The gate driving unit 130 generates and outputs gate signals in response to the gate control signal GCS. The gate driving unit 130 may sequentially output the gate signals. The gate signals are provided to the pixels PX row-by-row through the gate lines GL1 to GLm. The application time (e.g. a first horizontal period) of each gate signal includes a first period and a second period.

The data driving unit 140 generates and outputs analog data voltages corresponding to the image data DATA in response to the data control signal DCS. The data voltages are provided to the demux unit 150 through the drive lines DVL1 to DVLk.

The demux unit 150 connects the drive lines DVL1 to DVLk to odd-numbered data lines of the data lines DL1 to DLn during the first period in response to the switch control signal SWS. Further, the demux unit 150 connects the drive lines DVL1 to DVLk to even-numbered data lines of the data lines DL1 to DLn during the second period in response to the switch control signal SWS.

Hereinafter, the odd-numbered data lines and the even-numbered data lines of the data lines DL1 to DLn are referred to as first data lines and second data lines, respectively.

During the first period, data voltages are provided to pixels PX connected to the first data lines through the drive lines DVL1 to DVLk and the first data lines. During the second period, data voltages are provided to pixels connected to the second data lines through the drive lines DVL1 to DVLk and the second data lines.

The pixels PX receive data voltages in response to gate signals, and charge the received data voltages. The pixels PX display grayscale values corresponding to the charged data voltages, resulting in an image being displayed.

The transistor TR of each pixel PXij receives a data voltage through the data line DLj in response to a gate signal received through the gate line GLi. The transistor TR provides the data voltage to the pixel electrode PE. The common electrode CE receives a common voltage VCOM. Therefore, a voltage corresponding to the data voltage is charged in the liquid crystal capacitor CLC.

The data voltages may be delayed due to the RC delay caused by the self-resistance of the drive lines DVL1 to DVLk and the data lines DL1 to DLn, and parasitic capacitors.

In an exemplary embodiment of the inventive concept, the channel resistance of switch transistors disposed in the demux unit 150 decreases, and the drain-source current Ids of the switch transistors increases. Therefore, the amount of current provided to the pixels PX via the switch transistors increases, and the charging rate of the pixels PX may thus be improved. This configuration will be described in further detail below.

The timing controller 120 may be mounted in the form of an integrated circuit chip on a printed circuit board (PCB) and connected to the gate driving unit 130 and the data driving unit 140.

The gate driving unit 130 and the data driving unit 140 may be mounted in the form of a plurality of driving chips on a flexible PCB, and may be connected to the display panel 110 by, for example, a Tape Carrier Package (TCP) method.

However, exemplary embodiments of the inventive concept are not limited thereto. For example, the gate driving unit 130 and the data driving unit 140 may be mounted in the form of a plurality of driving chips on the display panel 110 by a Chip on Glass (COG) method, or other methods.

For example, the gate driving unit 130 may be provided simultaneously with transistors of the pixels PX11 to PXmn, and mounted on the display panel 110 in the form of an Amorphous Silicon TFT Gate drive circuit (ASG) or an Oxide Silicon TFT Gate driver circuit (OSG). However, exemplary embodiments of the inventive concept are not limited thereto.

The demux unit 150 may be disposed in the display panel 110 between the data driving unit 140 and the pixels PX11 to PXmn (e.g., the pixels PX shown in FIG. 1 may be numbered in the form of PX11 to PXmn from the top-left portion of the pixel matrix to the bottom-right portion of the pixel matrix).

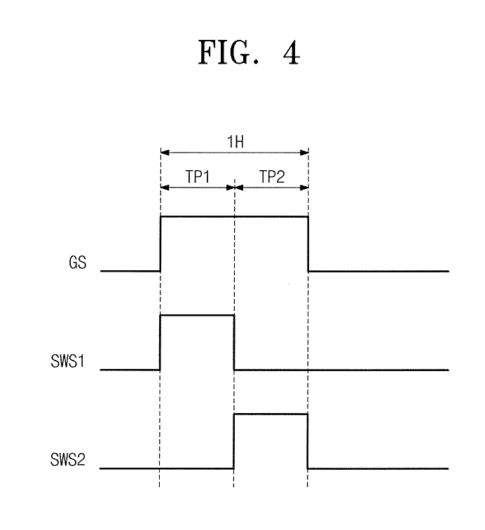

FIG. 3 illustrates a configuration of the demux unit 150 illustrated in FIG. 1 according to an exemplary embodiment of the inventive concept. FIG. 4 is a timing diagram illustrating the operation of the demux unit 150 according to an exemplary embodiment of the inventive concept.

For convenience of description, only pixels PX connected to the first gate line GL1 of FIG. 1 are illustrated in FIG. 3.

Referring to FIG. 3, the demux unit 150 is turned on in response to the switch control signal SWS. The demux unit 150 includes a plurality of switch transistors ST1 and ST2 for selectively connecting the drive lines DVL1 to DVLk to the first data lines and the second data lines.

The switch transistors ST1 and ST2 include a plurality of first switch transistors ST1 connecting the drive lines DVL1 to DVLk to the first data lines, and a plurality of second switch transistors ST2 connecting the drive lines DVL1 to DVLk to the second data lines. The first switch transistors ST1 and the second switch transistors ST2 may have the same configuration.

The first switch transistors ST1 are connected to a first switch line SWL1, and the second switch transistors ST2 are connected to a second switch line SWL2. The switch control signal SWS includes a first switch signal SWS1 and a second switch signal SWS2, as shown in FIG. 4. The first switch line SWL1 receives the first switch signal SWS1, and the second switch line SWL2 receives the second switch signal SWS2.

The first switch transistors ST1 each include a first gate electrode connected to the first switch line SWL1, a first source electrode connected to a corresponding drive line of the drive lines DVL1 to DVLk, and a first drain electrode connected to a corresponding first data line of the first data lines.

The second switch transistors ST2 each include a second gate electrode connected to the second switch line SWL2, a second source electrode connected to a corresponding drive line of the drive lines DVL1 to DVLk, and a second drain electrode connected to a corresponding second data line of the second data lines.

The first switch transistors ST1 connect the drive lines DVL1 to DVLk to the first data lines in response to the first switch signal SWS1 received through the first switch line SWL1. The second switch transistors ST2 connect the drive lines DVL1 to DVLk to the second data lines in response to the second switch signal SWS2 received through the second switch line SWL2.

Referring to FIG. 4, a period 1H of a gate signal GS applied to each of the gate lines GL1 to GLm includes a first period TP1 and a second period TP2. The period 1H of the gate signal GS may be defined as a period (e.g., an activation period) of the gate signal GS having a high level.

During the first period TP1, the first switch signal SWS1 is provided to the first switch transistors ST1 through the first switch line SWL1. As a result, during the first period TP1, the first switch transistors ST1 connect the drive lines DVL1 to DVLk to the first data lines. The first period TP1 may be defined as a period of the first switch signal SWS1 having a high level.

During the second period TP2, the second switch signal SWS2 is provided to the second switch transistors ST2 through the second switch line SWL2. As a result, during the second period TP2, the second switch transistors ST2 connect the drive lines DVL1 to DVLk to the second data lines. The second period TP2 may be defined as a period of the second switch signal SWS2 having a high level.

During the first period TP1, pixels PX connected to the first data lines receive data voltages through the drive lines DVL1 to DVLk and the first data lines connected to the first switch transistors ST1. During the second period TP2, pixels PX connected to the second data lines receive data voltages through the drive lines DVL1 to DVLk and the second data lines connected to the second switch transistors ST2.

Therefore, during the first period TP1, data voltages are charged in the pixels PX connected to the first data lines, and during the second period TP2, data voltages are charged in the pixels PX connected to the second data lines.

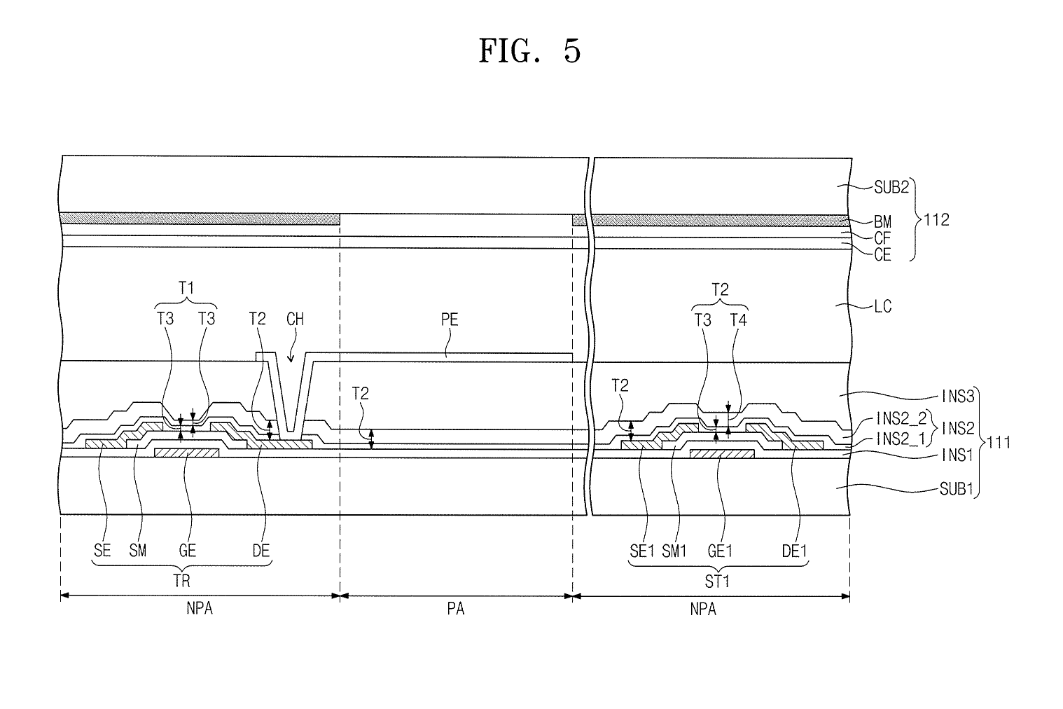

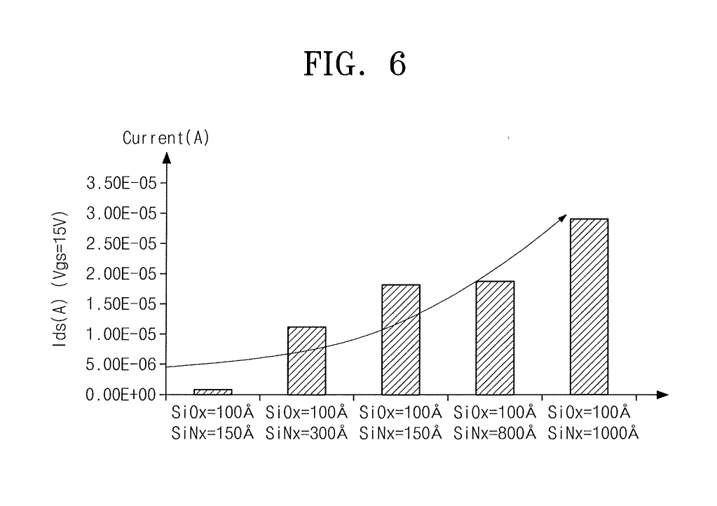

FIG. 5 illustrates a cross-sectional view of a display panel in an area in which a transistor of any one pixel illustrated in FIG. 1 and any one switch transistor illustrated in FIG. 3 are disposed according to an exemplary embodiment of the inventive concept. FIG. 6 shows exemplary experimentation results regarding the source-drain current of switch transistors according to the thickness of a second insulating layer disposed on the switch transistors according to an exemplary embodiment of the inventive concept.

In FIG. 5, a sectional view of one transistor TR and one first switch transistor ST1 is exemplarily illustrated. According to exemplary embodiments, other transistors TR in the display device 100 may have substantially the same configuration as the TR shown in FIG. 5, and other switch transistors ST1 and ST2 in the display device 100 may have substantially the same configuration as the first switch transistor ST1 illustrated in FIG. 5.

Referring to FIG. 5, the display panel 110 includes a first substrate 111, a second substrate 112 disposed to face the first substrate 111, and a liquid crystal layer LC disposed between the first and second substrates 111 and 112.

The first substrate 111 includes a first base substrate SUB1, a transistor TR and a first switch transistor ST1 disposed on the first base substrate SUB1. The first base substrate SUB1 may be, for example, a transparent or non-transparent insulating substrate. For example, the first base substrate SUB1 may be a silicon substrate, a glass substrate, or a plastic substrate. However, exemplary embodiments of the inventive concept are not limited thereto.

For example, a gate electrode GE of the transistor TR and a first gate electrode GE1 of the first switch transistor ST1 are disposed on the first base substrate SUB1.

On the first base substrate SUB1, a first insulating layer INS1 is disposed to cover the gate electrode GE and the first gate electrode GE1. The first insulating layer INS1 may include, for example, an inorganic material, and may be referred to herein as a gate insulator.

A semiconductor layer SM of the transistor TR is disposed on the first insulating layer INS1 covering the gate electrode GE. A first semiconductor layer SM1 of the first switch transistor ST1 is disposed on the first insulating layer INS1 covering the first gate electrode GE1. The semiconductor layer SM and the first semiconductor layer SM1 may each include an active layer and an ohmic contact layer.

On the semiconductor layer SM and the first insulating layer INS1, a source electrode SE and a drain electrode DE of the transistor TR are disposed to be spaced from each other. The semiconductor layer SM forms a conductive channel between the source electrode SE and the drain electrode DE.

On the first semiconductor layer SM1 and the first insulating layer INS1, a first source electrode SE1 and a first drain electrode DE1 of the first switch transistor ST1 are disposed to be spaced from each other. The first semiconductor layer SM1 forms a conductive channel between the first source electrode SE1 and the first drain electrode DE1.

A second insulating layer INS2 is disposed on the first insulating layer INS1 and covers the transistor TR and the first switch transistor ST1. The second insulating layer INS2 may include, for example, an inorganic material, and may be referred to herein as a passivation layer. The second insulating layer INS2 covers the upper portion of the exposed semiconductor layer SM of the transistor TR and the upper portion of the exposed first semiconductor layer SM1 of the first switch transistor ST1.

The second insulating layer INS2 disposed on the conductive channel of the transistor TR has a first thickness T1. The second insulating layer INS2 disposed on the conductive channel of the first switch transistor ST1 has a second thickness T2. In an exemplary embodiment, the second thickness T2 is larger than the first thickness T1.

The second insulating layer INS2 has the second thickness T2 in all areas except for areas in which the conductive channel of the transistor TR is disposed. For example, according to exemplary embodiments, an entirety of the second insulating layer INS2 has the second thickness T2 except for areas in which the conductive channel of the transistor TR is disposed.

The second insulating layer INS2 includes a first sub-insulating layer INS2_1 disposed on the first insulating layer INS1 and covering the transistor TR and the first switch transistor ST1, and a second sub-insulating layer INS2_2 disposed on the first sub-insulating layer INS2_1.

The first and second sub-insulating layers INS2_1 and INS2_2 may include different inorganic materials. For example, in an exemplary embodiment, the first sub-insulating layer INS2_1 includes silicon oxide (SiOₓ) and the second sub-insulating layer 11\152_2 includes silicon nitride (SiNₓ). However, exemplary embodiments of the inventive concept are not limited thereto.

Each of the first and second sub-insulating layers INS2_1 and INS2_2 disposed on the conductive channel of the transistor TR has a third thickness T3. Referring to the transistor TR, the sum of the two third thicknesses T3 is equal to the first thickness T1.

The first sub-insulating layer INS2_1 disposed on the conductive channel of the first switch transistor ST1 has the third thickness T3. The second sub-insulating layer INS2_2 disposed on the conductive channel of the first switch transistor ST1 has a fourth thickness T4. In an exemplary embodiment, the fourth thickness T4 is larger than the third thickness T3. Referring to the first switch transistor ST1, the sum of the third thickness T3 and the fourth thickness T4 is equal to the second thickness T2.

In areas except for areas in which the conductive channel of the transistor TR is disposed, the first sub-insulating layer INS2_1 has the third thickness T3 and the second sub-insulating layer INS2_2 has the fourth thickness T4. For example, according to exemplary embodiments, an entirety of the first sub-insulating layer INS2_1 has the third thickness T3 except for areas in which the conductive channel of the transistor TR is disposed, and an entirety of the second sub-insulating layer INS2_2 has the fourth thickness T4 except for areas in which the conductive channel of the transistor TR is disposed.

A third insulating layer INS3 is disposed on the second insulating layer INS2. The third insulating layer INS3 may include, for example, an organic material. The third insulating layer INS3 may serve to planarize the top surface of the first substrate 111.

A contact hole CH exposing a predetermined area of the drain electrode DE passes through the third and second insulating layers INS3 and INS2. The drain electrode DE of the transistor TR is electrically connected to the pixel electrode PE via the contact hole CH.

The pixel electrode PE is disposed in a pixel area PA. Each pixel PX has a corresponding pixel area PA. The areas next to the pixel area PA are defined as non-pixel areas NPA.

The pixel electrode PE may be made of, for example, a transparent conductive material. For example, the pixel electrode PE may be made of a transparent conductive material such as indium tin oxide (ITO), indium zinc oxide (IZO), and indium tin zinc oxide (ITZO). However, exemplary embodiments of the inventive concept are not limited thereto. An alignment layer may be disposed on the third insulating layer INS3 and may cover the pixel electrode PE.

The second substrate 112 includes a second base substrate SUB2, a black matrix BM, a color filter CF, and a common electrode CE. The second base substrate SUB2 is disposed to face the first base substrate SUB1.

The second base substrate SUB2 may be, for example, a transparent or non-transparent insulating substrate. For example, the second base substrate SUB2 may be a silicon substrate, a glass substrate, or a plastic substrate. However, exemplary embodiments of the inventive concept are not limited thereto.

In the non-pixel area NPA, the black matrix BM is disposed under the second base substrate SUB2. The color filter CF is disposed under the second base substrate SUB2 to correspond to the pixel PX. The color filter CF is disposed to cover the black matrix BM. The color filter CF provides light passing through the pixel PX with colors. The color filter CF may be any one of, for example, a red color filter, a green color filter, or a blue color filter. However, exemplary embodiments of the inventive concept are not limited thereto.

The black matrix BM blocks unwanted light during the process of displaying the image. For example, the black matrix BM may block light leakage caused by abnormal behavior of liquid crystal molecules which may occur at the edge of the pixel area PA. Further, the black matrix BM may prevent color mixing which may appear at the edge of the color filter CF.

The common electrode CE is disposed under the color filter CF. The common electrode CE may be made of, for example, a transparent conductive material. For example, the common electrode CE may be made of a transparent conductive material such as indium tin oxide (ITO), indium zinc oxide (IZO), and indium tin zinc oxide (ITZO). However, exemplary embodiments of the inventive concept are not limited thereto. An alignment layer may be disposed under the common electrode CE.

A liquid crystal capacitor CLC is provided by means of the pixel electrode PE, the common electrode CE, and the liquid crystal layer LC disposed between the pixel electrode PE and the common electrode CE. The pixel electrode PE receives a data voltage when the transistor TR is turned on, and the common electrode CE receives a common voltage VCOM.

An electric field is formed between the pixel electrode PE and the common electrode CE by a voltage level difference between the data voltage applied to the pixel electrode PE and the common voltage VCOM applied to the common electrode CE.

Liquid crystal molecules in the liquid crystal layer LC are driven by the electric field formed between the pixel electrode PE and the common electrode CE. Light transmittance is controlled by the liquid crystal molecules driven by the electric field, resulting in an image being displayed.

A backlight unit that provides the display panel 110 with light may be disposed behind the display panel 110.

During the manufacture of the first substrate 111 of the display panel 110, the first substrate 111 is prepared and then subjected to a heat treatment process. For example, according to an exemplary embodiment, the first substrate 111 may be heat-treated for about one hour at a temperature of about 350° C. The heat treatment may stabilize the display panel 110.

For example, voltage-current characteristics of the transistors TR may vary due to process errors. That is, threshold voltage dispersion of the transistors TR may become large. The threshold voltage dispersion of the transistors TR may be reduced, for example, by the heat treatment process.

In an exemplary embodiment, silicon nitride in the second sub-insulating layer INS2_2 includes ionized hydrogen (H⁺). During the heat treatment process, the ionized hydrogen in silicon nitride may diffuse into the semiconductor layer SM and the first semiconductor layer SM1.

Since silicon nitride having a larger thickness contains a relatively larger amount of ionized hydrogen, the amount of diffusing ionized hydrogen is proportional to the thickness of the silicon nitride. The amount of ionized hydrogen diffusing into the first semiconductor layer SM1 is larger than the amount of ionized hydrogen diffusing into the semiconductor layer SM.

The ionized hydrogen serves to lower the resistance of the semiconductor layer SM and the first semiconductor layer SM1. The resistance value is lowered in proportion to the amount of ionized hydrogen. Therefore, the resistance value of the first semiconductor layer SM1 may be lower than that of the semiconductor layer SM.

As a result of lowering the resistance value of the first semiconductor layer SM1, voltage-current characteristics of the first and second switch transistors ST1 and ST2 may be improved. For example, by way of the ionized hydrogen, the resistance value of the first semiconductor layer SM1 is lowered, and the drain-source current Ids flowing through the channel of the first switch transistors ST1 increases.

Since the second switch transistors ST2 have the same configuration as the first switch transistors ST1, the resistance value of the second semiconductor layer SM2 is lowered, and the drain-source current Ids flowing through the channel of the second switch transistors ST2 increases.

Referring to FIG. 6, when the gate-source voltage Vgs of the first and second switch transistors ST1 and ST2 is set to about 15 V, the third thickness T3 of the first sub-insulating layer INS2_1 including silicon oxide (SiOx) is about 100 Å. In addition, the fourth thickness T4 of the second sub-insulating layer INS2_2 may be larger than about 100 Å and less than or equal to about 1,000 Å.

Referring to the exemplary experimentation results of FIG. 6, when the fourth thickness T4 of the second sub-insulating layer INS2_2 including silicon nitride was about 150 Å, about 300 Å, about 500 Å, about 800 Å, and about 1,000 Å, the drain-source current Ids was measured. Ås shown in FIG. 6, as the fourth thickness T4 of the second sub-insulating layer INS2_2 increases, the drain-source current Ids of the first and second switch transistors ST1 and ST2 increases.

In a comparative example, data voltages are charged in such a way that the period 1H of the gate signal GS is divided into the first and second periods TP1 and TP2. As a result, the charging time may be insufficient unlike a scenario in which the data voltages are charged during the period 1H of the gate signal without using a demux unit. Furthermore, the thickness of the second sub-insulating layer INS2_2 on the channel of the first and second switch transistors ST1 and ST2 may be equal to the thickness of the second sub-insulating layer INS2_2 disposed on the channel of the transistors TR.

In this case, the data voltages are delayed due to the RC delay caused by the self-resistance of the drive lines DVL1 to DVLk and the data lines DL1 to DLn and parasitic capacitors, which may result in the charging rate of the pixels PX being reduced.

According to exemplary embodiments of the inventive concept, the channel resistance of the first and second switch transistors ST1 and ST2 disposed in the demux unit 150 is reduced, and the drain-source current Ids of the first and second switch transistors ST1 and ST2 increases. Therefore, the amount of current provided to the pixels PX through the first and second switch transistors ST1 and ST2 increases. As a result, the pixels PX may be more quickly charged. That is, the charging rate of the pixels PX may be improved according to exemplary embodiments of the inventive concept.

Thus, the display device 100 according to exemplary embodiments of the inventive concept may improve the charging rate of the pixels PX.

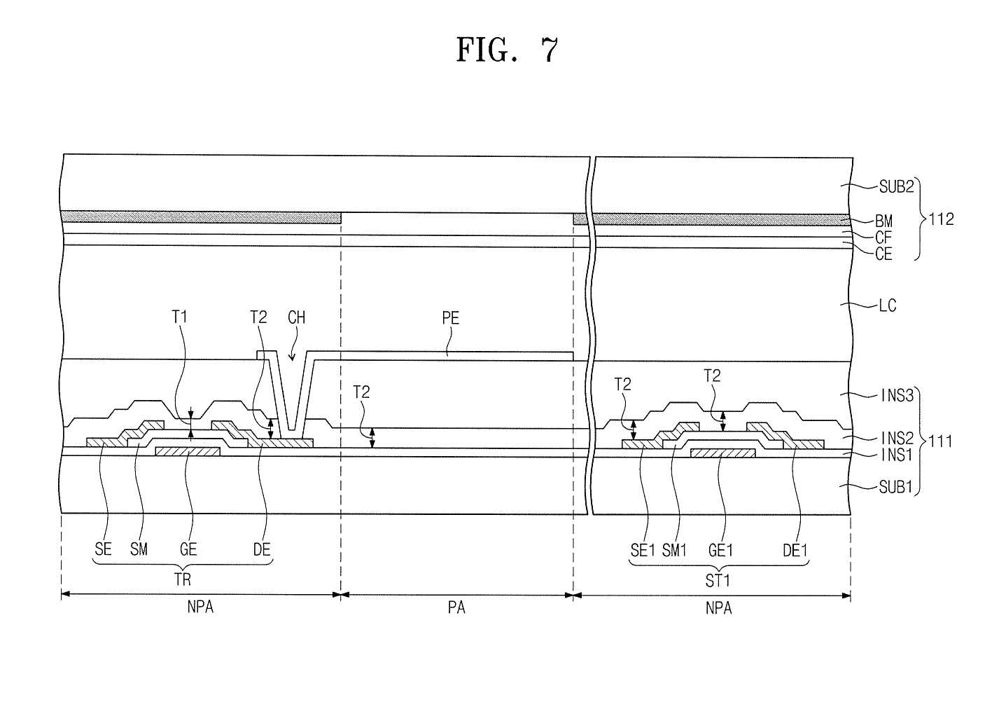

FIG. 7 illustrates a cross-sectional view of a display panel of a display device according to an exemplary embodiment of the inventive concept.

The cross-section of the display panel illustrated in FIG. 7 is a cross-section of an area corresponding to the cross-section of the display panel 110 illustrated in FIG. 5. The cross-section of the display panel according to the exemplary embodiment in FIG. 7 has the same configuration as the cross-section of the display panel 110 illustrated in FIG. 5, except for the configuration of the second insulating layer INS2. Therefore, for convenience of explanation, a further description of elements and configurations previously described with reference to FIG. 5 may be omitted herein.

Referring to FIG. 7, the second insulating layer INS2 is disposed on the first insulating layer INS1 and covers the transistor TR and the first switch transistor ST1. The second insulating layer INS2 is provided as a single layer. The second insulating layer INS2 includes, for example, silicon nitride (SiNₓ). However, exemplary embodiments of the inventive concept are not limited thereto.

The second insulating layer INS2 disposed on the conductive channel of the transistor TR has a first thickness T1. The second insulating layer INS2 disposed on the conductive channel of the first switch transistor ST1 has a second thickness T2, which is larger than the first thickness T1. The second insulating layer INS2 has the second thickness T2 in an area except for areas in which the conductive channel of the transistor TR and the conductive channel of the first switch transistor ST1 are disposed. That is, according to an exemplary embodiment, the entire area of the second insulating layer INS2 other than the areas in which the conductive channels of the transistor TR and the first switch transistor ST1 are disposed as the second thickness T2.

According to exemplary embodiments, the resistance value of the first semiconductor layer SM1 is lowered due to ionized hydrogen of silicon nitride. As a result, voltage-current characteristics of the first and second switch transistors ST1 and ST2 are improved. Therefore, the drain-source current Ids flowing through the conductive channel of the first and second switch transistors ST1 and ST2 increases. As a result, the amount of current provided to the pixels PX through the first and second switch transistors ST1 and ST2 increases, resulting in an improvement of the charging rate of the pixels PX.

Thus, the display device according to exemplary embodiments of the inventive concept may improve the charging rate of the pixels PX.

While the present inventive concept has been particularly shown and described with reference to the exemplary embodiments thereof, it will be understood by those of ordinary skill in the art that various changes in form and detail may be made therein without departing from the spirit and scope of the present inventive concept as defined by the following claims.

What is claimed is:

1. A display device, comprising:
a plurality of pixels, wherein each pixel comprises a transistor connected to a corresponding gate line of a plurality of gate lines and a corresponding data line of a plurality of data lines, and a liquid crystal capacitor connected to the transistor;
a plurality of switch transistors receiving data voltages and selectively applying the data voltages to odd-numbered data lines and even-numbered data lines of the data lines; and
an insulating layer disposed on the transistors and the switch transistors,
wherein the insulating layer disposed on a conductive channel of each of the transistors has a first thickness, and the insulating layer disposed on a conductive channel of each of the switch transistors has a second thickness larger than the first thickness.

2. The display device of claim 1, wherein an entirety of the insulating layer has the second thickness except for areas in which the conductive channel of each of the transistors is disposed.

3. The display device of claim 1, wherein the insulating layer comprises an inorganic material.

4. The display device of claim 1, wherein the insulating layer comprises:
a first sub-insulating layer disposed on the transistors and the switch transistors; and
a second sub-insulating layer disposed on the first sub-insulating layer,
wherein the first and second sub-insulating layers comprise different inorganic materials.

5. The display device of claim 4, wherein the first sub-insulating layer comprises silicon oxide.

6. The display device of claim 5, wherein the second sub-insulating layer comprises silicon nitride.

7. The display device of claim 6, wherein each of the first and second sub-insulating layers disposed on the conductive channel of each of the transistors has a third thickness.

8. The display device of claim 6, wherein the first sub-insulating layer disposed on the conductive channel of each of the switch transistors has a third thickness and the second sub-insulating layer disposed on the conductive channel of each of the switch transistors has a fourth thickness larger than the third thickness.

9. The display device of claim 6, wherein an entirety of the first sub-insulating layer has a third thickness except for areas in which the conductive channel of each of the transistors is disposed, an entirety of the second sub-insulating layer has a fourth thickness except for areas in which the conductive channel of each of the transistors is disposed, and the fourth thickness is larger than the third thickness.

10. The display device of claim 6, wherein the second sub-insulating layer has a thickness larger than about 100 Å and less than or equal to about 1,000 Å.

11. The display device of claim 1, further comprising:
a base substrate, wherein the transistors and the switch transistors are disposed on the base substrate; and
an organic insulating layer disposed on the insulating layer,
wherein each liquid crystal capacitor comprises:
a pixel electrode connected to a corresponding transistor via a contact hole passing through the insulating layer and the organic insulating layer;
a common electrode facing the pixel electrode; and
a liquid crystal layer disposed between the pixel electrode and the common electrode.

12. The display device of claim 11, wherein each of the transistors comprises:
a gate electrode connected to the corresponding gate line;
a source electrode connected to the corresponding data line;
a drain electrode connected to the pixel electrode; and
a semiconductor layer disposed between the gate electrode and the source and drain electrodes, wherein the semiconductor layer forms the conductive channel of the transistor between the source electrode and the drain electrode.

13. The display device of claim 12, wherein
each of the gate lines receives a gate signal comprising a first period and a second period, and
the switch transistors comprise:
a plurality of first switch transistors receiving the data voltages during the first period and applying the data voltages to the odd-numbered data lines; and
a plurality of second switch transistors receiving the data voltages during the second period and applying the data voltages to the even-numbered data lines.

14. The display device of claim 13, wherein
each of the first switch transistors comprises:
a first gate electrode receiving a first switch signal;
a first source electrode receiving a corresponding data voltage of the data voltages;
a first drain electrode connected to a corresponding odd-numbered data line of the odd-numbered data lines; and
a first semiconductor layer disposed between the first gate electrode and the first source and first drain electrodes, wherein the first semiconductor layer forms the conductive channel of a corresponding first switch transistor between the first source electrode and the first drain electrode, and
each of the second switch transistors comprises:
a second gate electrode receiving a second switch signal;
a second source electrode receiving a corresponding data voltage of the data voltages;
a second drain electrode connected to a corresponding even-numbered data line of the even-numbered data lines; and
a second semiconductor layer disposed between the second gate electrode and the second source and second drain electrodes, wherein the second semiconductor layer forms the conductive channel of a corresponding second switch transistor between the second source electrode and the second drain electrode.

15. The display device of claim 1, wherein the insulating layer comprises silicon nitride.

16. A display device, comprising:
a gate driving unit providing a plurality of pixels of a display panel with a plurality of gate signals through a plurality of gate lines;
a data driving unit providing a demultiplexing unit with a plurality of data signals through a plurality of drive lines;
the demultiplexing unit providing the pixels with the data signals through a plurality of data lines;
a timing controller generating a gate control signal that controls an operation timing of the gate driving unit, a data control signal that controls an operation timing of the data driving unit, and a switch control signal controlling an operation of the demultiplexing unit; and
the display panel, comprising:
the pixels, wherein each pixel comprises a transistor connected to a corresponding gate line of the gate lines and a corresponding data line of the data lines;
a plurality of switch transistors receiving data voltages and applying the data voltages to the data lines; and
an insulating layer disposed on the transistors and the switch transistors,
wherein the insulating layer disposed on a conductive channel of each of the transistors has a first thickness, and the insulating layer disposed on a conductive channel of each of the switch transistors has a second thickness larger than the first thickness.

17. The display device of claim 16, wherein an entirety of the insulating layer has the second thickness except for areas in which the conductive channel of each of the transistors is disposed.

18. The display device of claim 16, wherein the insulating layer comprises:
a first sub-insulating layer disposed on the transistors and the switch transistors; and
a second sub-insulating layer disposed on the first sub-insulating layer,
wherein the first and second sub-insulating layers comprise different inorganic materials.

19. The display device of claim 18, wherein the first sub-insulating layer comprises silicon oxide and the second sub-insulating layer comprises silicon nitride.

20. The display device of claim 19, wherein an entirety of the first sub-insulating layer has a third thickness except for areas in which the conductive channel of each of the transistors is disposed, an entirety of the second sub-insulating layer has a fourth thickness except for areas in which the conductive channel of each of the transistors is disposed, and the fourth thickness is larger than the third thickness.
